(19) United States
(12) Patent Application Publication
(10) Pub. No.: US 2025/0233561 A1
(43) Pub. Date: Jul. 17, 2025

(54) HYBRID PREDISTORTION IN A WIRELESS TRANSMISSION CIRCUIT

(71) Applicant: Qorvo US, Inc., Greensboro, NC (US)

(72) Inventors: George Maxim, Saratoga, CA (US); Nadim Khlat, Cugnaux (FR); Baker Scott, San Jose, CA (US)

(21) Appl. No.: 18/728,637

(22) PCT Filed: Jan. 18, 2023
(86) PCT No.: PCT/US2023/060804

§ 371 Date: Jul. 12, 2024

Related U.S. Application Data
(60) Provisional application No. 63/300,471, filed on Jan. 18, 2022.
(60) Provisional application No. 63/300,478, filed on Jan. 18, 2022.
(60) Provisional application No. 63/393,559, filed on Jul. 29, 2022.

(51) Int. Cl. H03F 1/32; H03F 3/195; H03F 3/24

(52) U.S. Cl. CPC H03F 1/3247; H03F 1/3282; H03F 3/195; H03F 3/245; H03F 2200/451; H03F 2201/3224; H03F 2201/3233

(57) ABSTRACT

Hybrid predistortion in a wireless transmission circuit is provided. The wireless transmission circuit includes a transceiver circuit that generates a radio frequency (RF) signal and a power amplifier circuit than amplifies the RF signal for transmission. In aspects disclosed herein, the transceiver circuit is configured to perform a digital predistortion(s) (DPD) on a digital version of the RF signal and the power amplifier circuit is configured to perform an analog predistortion(s) (APD) on the RF signal to collectively cancel varies types of distortions in the RF signal. By concurrently performing a combination of DPD and APD (a.k.a. hybrid predistortion) across the transceiver circuit and the power amplifier circuit, it is possible to effectively restore linearity in the RF signal and improve overall performance of the wireless transmission circuit with reduced footprint, cost, and computational complexity.

### PRIORITY APPLICATIONS

The present application claims priority to U.S. Provisional Patent Application Ser. No. 63/300,471, filed Jan. 18, 2022 and entitled “HYBRID DIGITAL AND ANALOG PRE-DISTORTION (DPD-APD) TX PATH LINEARIZATION FOR APT AND ET SYSTEMS,” which is incorporated herein by reference in its entirety.

The present application also claims priority to U.S. Provisional Patent Application Ser. No. 63/300,478, filed Jan. 18, 2022 and entitled “5G FEM-BASEBAND THERMAL MANAGEMENT WITH REAL-TIME PA TEMPERATURE FEEDBACK TO THE BASEBAND FOR ANALOG-ASSISTED DPD AND PMIC CONTROL,” which is incorporated herein by reference in its entirety.

The present application also claims priority to U.S. Provisional Patent Application Ser. No. 63/393,559, filed Jul. 29, 2022 and entitled “HYBRID PREDISTORTION IN A WIRELESS TRANSMISSION CIRCUIT,” which is incorporated herein by reference in its entirety.

### FIELD OF THE DISCLOSURE

The technology of the disclosure relates generally to a transmission circuit that performs a combination of digital and analog predistortions potentially responsive to thermal changes.

### BACKGROUND

Mobile communication devices have become increasingly common in current society for providing wireless communication services. The prevalence of these mobile communication devices is driven in part by the many functions that are now enabled on such devices. Increased processing capability in such devices means that mobile communication devices have evolved from being pure communication tools into sophisticated mobile multimedia centers that enable enhanced user experiences.

The redefined user experience relies on a higher data rate offered by advanced fifth generation (5G) and 5G new radio (5G-NR) technologies, which may transmit and receive a radio frequency (RF) signal(s) in a millimeter wave spectrum. Given that the RF signal(s) is more susceptible to attenuation and interference in the millimeter wave spectrum, state-of-the-art power amplifiers are often employed to amplify the RF signal(s) to appropriate power levels before transmission. Unfortunately, since the power amplifiers often include many nonlinear components (e.g., transistors), the power amplifiers can cause various distortions, such as amplitude-amplitude (AM-AM) and amplitude-phase (AM-PM) distortions, in the RF signal(s). Without proper correction, the distortions can introduce nonlinearity in the RF signal(s) that may compromise performance (e.g., spectrum regrowth, bit error rate, etc.) of the mobile communication devices.

Digital predistortion (DPD) is a linearization technique that has gained increasing popularity nowadays due to its ability to correct (a.k.a. offset) the distortions in the RF signal(s) and linearize the power amplifiers under different RF configurations and/or operating conditions. More specifically, a transceiver circuit applies inverse distortions on a digital version of the RF signal(s) to thereby cancel the distortions in the RF signal(s). To cancel the distortions in the RF signal(s), a pre-distorter in the transceiver circuit needs to solve rather complex polynomials based on a set of predetermined coefficients. Thus, to cancel the distortions under various RF configurations (e.g., channel frequency, channel bandwidth, etc.) and/or operating conditions (e.g., impedance, supply voltage, temperature, etc.), the transceiver circuit must store multiple sets of the predetermined coefficients in local memory, which can lead to increased footprint, cost, and computational complexity. Hence, it is desirable for the transceiver circuit to store as few sets of coefficients as possible, and still be able to cancel distortions under different RF configurations and/or operating conditions.

### SUMMARY

Aspects of the disclosure relate to hybrid predistortion in a wireless transmission circuit. The wireless transmission circuit includes a transceiver circuit that generates a radio frequency (RF) signal and a power amplifier circuit that amplifies the RF signal for transmission. In aspects disclosed herein, the transceiver circuit is configured to perform a digital predistortion(s) (DPD) on a digital version of the RF signal and the power amplifier circuit is configured to perform an analog predistortion(s) (APD) on the RF signal to cancel varies types of distortions in the RF signal. As an example, the transceiver circuit can perform DPD to correct memory distortion in the RF signal, and the power amplifier circuit can perform APD to correct memoryless distortion in the RF signal. By concurrently performing a combination of DPD and APD (a.k.a. hybrid predistortion) across the transceiver circuit and the power amplifier circuit, it is possible to restore linearity in the RF signal and improve overall performance of the wireless transmission circuit with reduced footprint, cost, and computational complexity.

In another aspect, temperature values at the power amplifier circuit may be provided to the transceiver circuit and the power amplifier circuit and adjustments made to correct temperature-change-induced nonlinearities.

In one aspect, a wireless transmission circuit is provided. The wireless transmission circuit includes a transceiver circuit. The transceiver circuit includes a digital signal processing circuit. The digital signal processing circuit is configured to generate a digital signal. The transceiver circuit also includes a DPD circuit. The DPD circuit is configured to perform at least one selected form of DPD on the digital signal. The transceiver circuit also includes a signal conversion circuit. The signal conversion circuit is configured to convert the predistorted digital signal into an RF signal. The wireless transmission circuit also includes a power amplifier circuit. The power amplifier circuit includes an APD circuit. The APD circuit is configured to perform at least one selected form of APD on the RF signal.

Those skilled in the art will appreciate the scope of the present disclosure and realize additional aspects thereof after reading the following detailed description of the preferred aspects in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary existing wireless transmission circuit, wherein a power amplifier circuit can introduce various types of distortions in a radio frequency (RF) signal when the power amplifier circuit amplifies the RF signal from a time-variant input power to a time-variant output power;

FIG. 1B is a schematic diagram providing an exemplary illustration of an output stage of the power amplifier circuit in FIG. 1A;

FIG. 2 is a schematic diagram of an exemplary wireless transmission circuit configured according to an aspect of the present disclosure to perform a hybrid of digital predistortion (DPD) and analog predistortion (APD) to correct various types of distortions in an RF signal;

FIG. 3 is a schematic diagram of an exemplary wireless transmission circuit configured according to an aspect of the present disclosure;

FIG. 4 is a schematic diagram providing an exemplary illustration of a power amplifier circuit in the wireless transmission circuit of FIG. 3 that can perform APD based on fewer sets of APD coefficients;

FIG. 5 is a block diagram of a wireless transmission circuit with a temperature sensor being used to adjust APD based on temperature changes in a front-end module (FEM);

FIG. 6 is a block diagram of a wireless transmission circuit that uses temperature correction from a temperature sensor to assist in predistortion; and

FIG. 7 is a block diagram of a wireless transmission circuit that may include multiple technologies in the FEM.

### DETAILED DESCRIPTION

The aspects set forth below represent the necessary information to enable those skilled in the art to practice the aspects and illustrate the best mode of practicing the aspects. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects of the disclosure relate to hybrid predistortion in a wireless transmission circuit. The wireless transmission circuit includes a transceiver circuit that generates a radio frequency (RF) signal and a power amplifier circuit that amplifies the RF signal for transmission. In aspects disclosed herein, the transceiver circuit is configured to perform a digital predistortion(s) (DPD) on a digital version of the RF signal and the power amplifier circuit is configured to perform an analog predistortion(s) (APD) on the RF signal to cancel various types of distortions in the RF signal. As an example, the transceiver circuit can perform DPD to correct memory distortion in the RF signal, and the power amplifier circuit can perform APD to correct memoryless distortion in the RF signal. By concurrently performing a combination of DPD and APD (a.k.a. hybrid predistortion) across the transceiver circuit and the power amplifier circuit, it is possible to restore linearity in the RF signal and improve overall performance of the wireless transmission circuit with reduced footprint, cost, and computational complexity.

In another aspect, temperature values at the power amplifier circuit may be provided to the transceiver circuit and the power amplifier circuit and adjustments made to correct temperature-change-induced nonlinearities.

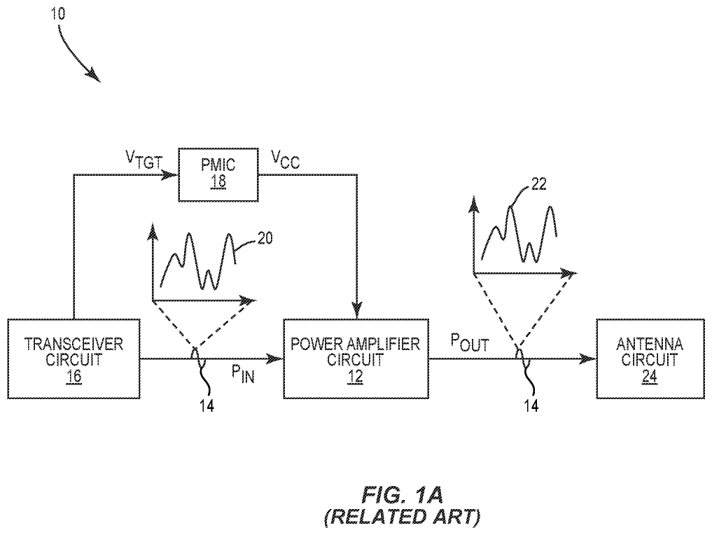

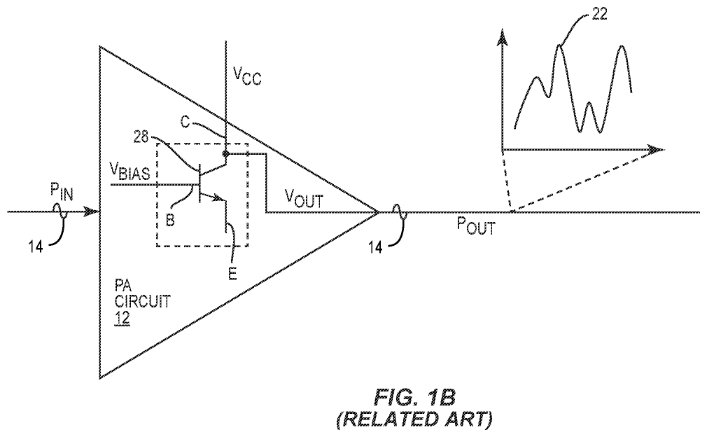

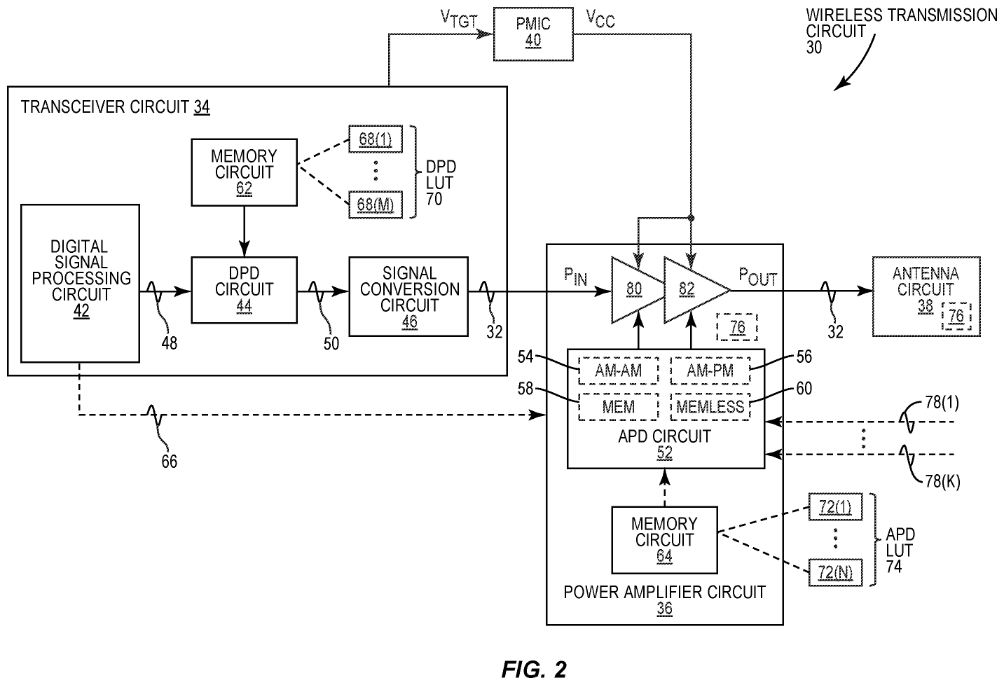

Before discussing the wireless transmission circuit according to the present disclosure, starting at FIG. 2, a brief discussion of an existing wireless transmission circuit is first provided with reference to FIGS. 1A and 1B to help understand various distortions that may be caused by a power amplifier circuit in an RF signal.

FIG. 1A is a schematic diagram of an exemplary existing wireless transmission circuit 10, wherein a power amplifier circuit 12 can introduce various types of distortions in an RF signal 14 when the power amplifier circuit 12 amplifies the RF signal 14 from a time-variant input power PIN to a time-variant output power POUT. The existing wireless transmission circuit 10 includes a transceiver circuit 16 and a power management integrated circuit (PMIC) 18. The transceiver circuit 16 is configured to generate the RF signal 14 and provide the RF signal 14 to the power amplifier circuit 12. The RF signal 14 is associated with a time-variant input power envelope 20 that defines the time-variant input power PIN.

The power amplifier circuit 12 is configured to amplify the RF signal 14 based on a modulated voltage Vcc, which can be an envelope tracking (ET) modulated voltage or an average power tracking (APT) modulated voltage. The amplified RF signal 14 is associated with a time-variant output power envelope 22 that defines the time-variant output power Pour. The power amplifier circuit 12 is further configured to provide the amplified RF signal 14 to an antenna circuit 24 for transmission in various RF bands.

The PMIC 18 is configured to generate the modulated voltage Vcc based on a modulated target voltage VTGT. The transceiver circuit 16 is configured to generate the modulated target voltage VTGT to closely track the time-variant input power envelope 20 of the RF signal 14. The PMIC 18, in turn, will generate the modulated voltage Vcc that tracks the modulated target voltage VTGT.

In an ideal situation, since the modulated target voltage V_{IGT} closely tracks the time-variant input power envelope 20 of the RF signal 14, the modulated voltage Vcc should also closely track the time-variant input power envelope 20. Further, if the power amplifier circuit 12 is perfectly linear, the time-variant output power envelope 22 should only be different from the time-variant input power envelope 20 in amplitude by a linear gain of the power amplifier circuit 12.

Unfortunately, the power amplifier circuit 12 can include nonlinear components (e.g., transistors) that can cause amplitude and/or phase distortion in the RF signal 14. As a result, the time-variant output power envelope 22 can be nonlinearly different from the time-variant input power envelope 20 in amplitude and/or phase.

FIG. 1B is a schematic diagram providing an exemplary illustration of an output stage 26 of the power amplifier circuit 12 in FIG. 1A. Common elements between FIGS. 1A and 1B are shown therein with common element numbers and will not be re-described herein.

The output stage 26 can include at least one transistor 28, such as a bipolar junction transistor (BJT) or a complementary metal-oxide semiconductor (CMOS) transistor. Taking the BJT as an example, the transistor 28 can include a base electrode B, a collector electrode C, and an emitter electrode E. The base electrode B is configured to receive a bias voltage VBIAS and the collector electrode C is configured to receive the modulated voltage Vcc. The collector electrode C is also coupled to the antenna circuit 24 and configured to output the amplified RF signal 14 at a modulated output voltage V_{OUT}. In this regard, the modulated output voltage V_{OUT} is substantially identical to the modulated voltage Vcc. As a result, the time-variant output power Pour will be a function of the modulated output voltage V_{OUT} and the modulated voltage Vcc. Understandably, the power amplifier circuit 12 will operate with good efficiency and linearity when the modulated voltage Vcc is aligned with the time-variant output power envelope 22.

However, since the PMIC 18 can intrinsically introduce group delay and/or nonlinearity in the modulated voltage Vcc, the modulated voltage Vcc may become misaligned with the time-variant input power envelope 20. As a result, the modulated output voltage V_{OUT}, and accordingly the time-variant output power envelope 22, of the amplified RF signal 14 will become misaligned with the time-variant input power envelope 20 to thereby cause an amplitude-amplitude (AM-AM) distortion and/or an amplitude-phase (AM-PM) distortion in the amplified RF signal 14.

In addition to the transistor 28, the power amplifier circuit 12 can include inductors and/or capacitors (at least parasitic capacitors) that can store electromagnetic energy. These energy-storing components can cause the time-variant output power Pour to not only depend on an instantaneous level of the time-variant input power PIN, but also a historical level(s) of the time-variant input power PIN. In this regard, the time-variant output power Pour is delayed from the time-variant input power PIN by a non-constant delay. Such a phenomenon is commonly referred to as a “memory distortion.” In contrast, if the time-variant output power Pour is delayed from the time-variant input power PIN by a constant delay, the RF signal 14 would still be considered as being distorted, but the distortion will instead be referred to as a “memoryless distortion.”

With reference back to FIG. 1A, the various types of distortions, such as AM-AM distortion, AM-PM distortion, memory distortion, and memoryless distortion, in the RF signal 14 can all lead to degraded linearity and performance of the power amplifier circuit 12. As such, it is desirable to correct the various distortions in the RF signal 14 as much as possible with the least possible implementation cost and complexity.

In this regard, FIG. 2 is a schematic diagram of an exemplary wireless transmission circuit 30 configured according to an aspect of the present disclosure to perform a combination of DPD and APD to correct various types of distortions in an RF signal 32. Herein, the wireless transmission circuit 30 includes a transceiver circuit 34 and a power amplifier circuit 36. The transceiver circuit 34 is configured to generate and provide the RF signal 32 to the power amplifier circuit 36 (and may sometimes be referred to as a baseband circuit or baseband processor (BBP)). The power amplifier circuit 36 is configured to amplify the RF signal 32 from a time-variant input power PIN to a time-variant output power Pour based on a modulated voltage Vcc. The power amplifier circuit 36 is coupled to an antenna circuit 38 that transmits the amplified RF signal 32 in one or more RF channels or bands.

The wireless transmission circuit 30 also includes a PMIC 40, which is configured to receive a modulated target voltage VTGT from the transceiver circuit 34 and generate the modulated voltage Vcc based on the modulated target voltage V_{IGT}. In a non-limiting example, the modulated voltage Vcc can be ET modulated or APT modulated.

For the same reasons as previously described in FIGS. 1A and 1B, the power amplifier circuit 36 can also cause various distortions, such as AM-AM distortion, AM-PM distortion, memory distortion, and/or memoryless distortion, in the RF signal 32 when the power amplifier circuit 36 amplifies the RF signal 32. As such, it is necessary to correct the various distortions in the RF signal 32 across a wide range of RF frequencies, with minimum possible cost and complexity impact, to help improve overall performance of the wireless transmission circuit 30. Moreover, it is also necessary to detect various changes in operating conditions and/or environments (e.g., temperature change, impedance change, voltage/current change, etc.) and adapt to the changes.

In aspects disclosed herein, the wireless transmission circuit 30 is configured to perform a combination of DPD and APD (a.k.a. hybrid predistortion) across the transceiver circuit 34 and the power amplifier circuit 36 to correct different distortions in the RF signal 32. As further discussed below, by performing APD in the power amplifier circuit 36 to correct at least some selected form of the distortions in the RF signal 32, as opposed to relying solely on the transceiver circuit 34 to correct all the distortions in the RF signal 32, it is possible to store a lesser number of coefficients in the transceiver circuit 34. As a result, it is possible to reduce the amount of physical memory required for storing the the coefficients, thus helping to reduce cost and footprint of the transceiver circuit 34. Further, by coping with the lesser number of coefficients, it is also possible to reduce computational complexity in the transceiver circuit 34.

According to one aspect of the present disclosure, the transceiver circuit 34 includes a digital signal processing circuit 42, a DPD circuit 44, and a signal conversion circuit 46. The digital signal processing circuit 42 is configured to generate a digital signal 48 (e.g., a digital baseband signal). The DPD circuit 44 is configured to perform at least one selected form of DPD on the digital signal 48 to generate a predistorted digital signal 50. The signal conversion circuit 46, which can include a digital-to-analog converter (DAC) and a frequency converter (not shown), is configured to covert the predistorted digital signal 50 into the RF signal 32.

The power amplifier circuit 36 includes an APD circuit 52. Herein, the APD circuit 52 can be configured to perform at least one selected form of APD on the RF signal 32. In a non-limiting example, the APD circuit 52 can include one or more of an AM-AM distortion correction block 54 (denoted as “AM-AM”), an AM-PM distortion correction block 56 (denoted as “AM-PM”), a memory distortion correction block 58 (denoted as “MEM”), and a memoryless distortion correction block 60 (denoted as “MEMLESS”). Specifically, the AM-AM distortion correction block 54 is configured to correct AM-AM distortion in the RF signal 32, the AM-PM distortion correction block 56 is configured to correct AM-PM distortion in the RF signal 32, the memory distortion correction block 58 is configured to correct memory distortion in the RF signal 32, and the memoryless distortion correction block 60 is configured to correct memoryless distortion in the RF signal 32.

The DPD circuit 44 and the APD circuit 52 can be configured to operate concurrently and perform DPD and APD in accordance with one or more predistortion schemes. Such predistortion schemes may be predetermined such that the DPD circuit 44 and the APD circuit 52 can collectively perform hybrid predistortion to correct any combination of the distortions (e.g., AM-AM distortion, AM-PM distortion, memory distortion, and memoryless distortion) in the RF signal 32.

As an example, such predetermined predistortion schemes can be stored in a transceiver memory circuit 62 and a power amplifier memory circuit 64. In a non-limiting example, the hybrid predistortion may be coordinated by the transceiver circuit 34 via a control signal 66.

In one aspect, the APD circuit 52 may be configured to perform APD on the RF signal 32 to correct the AM-AM distortion, and the DPD circuit 44 may be configured to perform DPD on the digital signal 48 to correct the AM-PM distortion in the RF signal 32. In case the APD circuit 52 is unable to correct completely the AM-AM distortion in the RF signal 32, the DPD circuit 44 may be further configured to perform DPD on the digital signal 48 to correct any residual AM-AM distortion in the RF signal 32.

In one aspect, the APD circuit 52 may be configured to perform APD on the RF signal 32 to correct the AM-PM distortion, and the DPD circuit 44 may be configured to perform DPD on the digital signal 48 to correct the AM-AM distortion in the RF signal 32. In case the APD circuit 52 is unable to correct completely the AM-PM distortion in the RF signal 32, the DPD circuit 44 may be further configured to perform DPD on the digital signal 48 to correct any residual AM-PM distortion in the RF signal 32.

In one aspect, the APD circuit 52 may be configured to perform APD on the RF signal 32 to correct both the AM-AM distortion and the AM-PM distortion in the RF signal 32. In this regard, in case the APD circuit 52 is unable to correct completely the AM-AM distortion and the AM-PM distortion in the RF signal 32, the DPD circuit 44 may be further configured to perform DPD on the digital signal 48 to correct any residual AM-AM distortion and AM-PM distortion in the RF signal 32.

In one aspect, the APD circuit 52 may be configured to perform APD on the RF signal 32 to correct the memoryless distortion, and the DPD circuit 44 may be configured to perform DPD on the digital signal 48 to correct the memory distortion in the RF signal 32. In case the APD circuit 52 is unable to correct completely the memoryless distortion in the RF signal 32, the DPD circuit 44 may be further configured to perform DPD on the digital signal 48 to correct any residual memoryless distortion in the RF signal 32.

According to one aspect of the disclosure, the transceiver circuit 34 can store multiple sets of DPD coefficients 68(1)-68(M) in a DPD lookup table (LUT) 70, and the power amplifier circuit 36 can store multiple sets of APD coefficients 72(1)-72(N) in an APD LUT 74. The sets of DPD coefficients 68(1)-68 (M) and the sets of APD coefficients 72(1)-72(N) may be prestored in the transceiver circuit 34 and the power amplifier circuit 36, for example, in accordance with the predetermined predistortion schemes. In addition, the sets of DPD coefficients 68(1)-68(M) and the sets of APD coefficients 72(1)-72(N) may also be calibrated based on an intended RF configuration and operating environment.

In exemplary aspects, the APD circuit 52 may be configured to normalize distortion such that a smaller set of coefficients may be used in the DPD circuit 44. That is, more distortion correction is shouldered by the APD circuit 52 so that the DPD circuit 44 may be simplified (or at least have lower memory requirements for the corresponding coefficient LUT).

In one aspect, the transceiver circuit 34 may also provide configuration of related information, such as frequency channel information, type of modulation, modulation bandwidth, signal peak-to-average ratio (PAR), and so on, via the control signal 66. Accordingly, the APD circuit 52 may adapt the APD in response to the configuration information received from the transceiver circuit 34. As an example, the APD circuit 52 can switch to a different set of APD coefficients among the multiple sets of APD coefficients 72(1)-72(N) for a particular form of APD or perform a different form of the APD. For example, for one set of configuration information, bias settings for the power amplifier circuit 36 may be used to provide APD. For another set of configuration information, load line modulation may be used to provide the APD. Many variations exist and are within the scope of the present disclosure.

In one aspect, the wireless transmission circuit 30 may incorporate one or more sensors 76, such as a temperature sensor, a supply voltage sensor, a process variation sensor, and so on. The sensors 76 may be provided at any location as appropriate in the wireless transmission circuit 30. The sensors 76 may be configured, collectively or individually, to provide one or more sensor signals 78(1)-78(K) to the APD circuit 52. Accordingly, the APD circuit 52 may adapt the APD in response to the sensory information received via the sensor signals 78(1)-78(K). As an example, the APD circuit 52 can switch to a different set of APD coefficients among the multiple sets of APD coefficients 72(1)-72(N) for a particular form of APD or perform a different form of the APD. More information about the use of sensors such as the temperature sensor is provided below.

It should be appreciated that, in a non-limiting example, the power amplifier circuit 36 can be a multi-stage power amplifier circuit including at least a driver stage amplifier 80 and an output stage amplifier 82. Understandably, the driver stage amplifier 80 and the output stage amplifier 82 are merely provided for the sake of illustration. It should be appreciated that the power amplifier circuit 36 can be configured to include additional stage amplifiers (e.g., an intermediate stage amplifier) without changing the operating principle of the APD circuit 52.

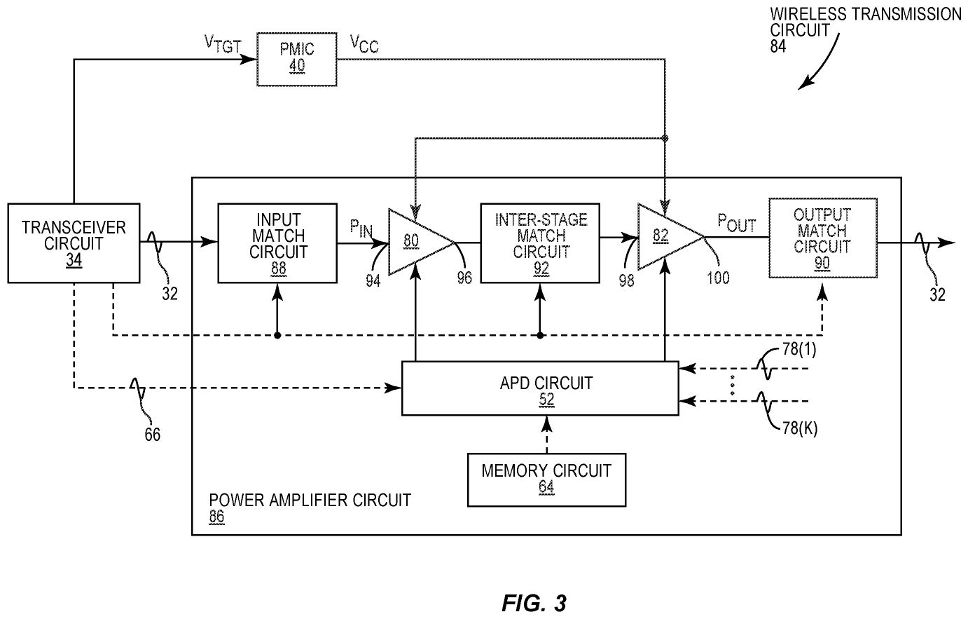

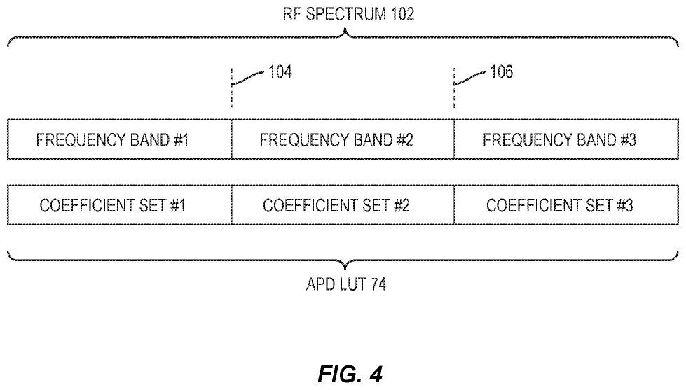

In one aspect, the power amplifier circuit 36 can be adapted to include multiple matching circuits to provide additional control knobs for the transceiver circuit 34. In this regard, FIG. 3 is a schematic diagram of an exemplary wireless transmission circuit 84 configured according to another aspect of the present disclosure. Common elements between FIGS. 2 and 4 are shown therein with common element numbers and will not be re-described herein.

Herein, the wireless transmission circuit 84 includes a power amplifier circuit 86, which is functionally equivalent to the power amplifier circuit 36 in FIG. 2. The power amplifier circuit 86 differs from the power amplifier circuit 36 in that the power amplifier circuit 86 further includes an input match circuit 88, an output match circuit 90, and at least one inter-stage match circuit 92. As illustrated, the input match circuit 88 is coupled to a driver stage input 94, the inter-stage match circuit 92 is coupled between a driver stage output 96 and an output stage input 98, and the output match circuit 90 is coupled to an output stage output 100.

In one aspect, the input match circuit 88, the output match circuit 90, and the inter-stage match circuit 92 can each include tunable circuits, such as current-type DACs (CDACs) and a programmable array of capacitors (PAC), that can provide additional control knobs to the transceiver circuit 34. In a non-limiting example, the transceiver circuit 34 can selectively adjust the tunable circuit in the input match circuit 88, the output match circuit 90, and/or the inter-stage match circuit 92 to thereby change a frequency response of the RF signal 32 so as to apply APD. Likewise, these knobs may be controlled by the APD circuit 52.

As illustrated in FIG. 4, by changing the frequency response of the RF signal 32, the APD circuit 52 can effectively perform APD with fewer sets of the APD coefficients 72(1)-72(N).

In a non-limiting example, the APD circuit 52 is configured to perform APD on an RF spectrum 102 that spans across frequency band #1 (a.k.a. lower frequency bad), frequency band #2 (a.k.a. middle frequency band), and frequency band #3 (a.k.a. upper frequency band). Accordingly, the APD LUT 74 needs to store three sets of the coefficients (coefficient set #1, coefficient set #2, and coefficient set #3) to be used for the frequency band #1, the frequency band #2, and the frequency band #3, respectively. For example, the APD circuit 52 will perform APD based on the coefficient set #1 if the RF signal 32 is transmitted in the frequency band #1, perform APD based on the coefficient set #2 if the RF signal 32 is transmitted in the frequency band #2, or perform APD based on the coefficient set #3 if the RF signal 32 is transmitted in the frequency band #3.

However, if the RF signal 32 is supposed to be transmitted in the frequency band #1 and the transceiver circuit 34 can change the frequency response of the RF signal 32 to be closer to a lower boundary 104 of the frequency band #2, the APD circuit 52 can then perform APD based on the coefficient set #2. Similarly, if the RF signal 32 is supposed to be transmitted in the frequency band #3 and the transceiver circuit 34 can change the frequency response of the RF signal 32 to be closer to an upper boundary 106 of the frequency band #2, the APD circuit 52 can then perform APD based on the coefficient set #2. As such, the APD LUT 74 only needs to store the coefficient set #2. As a result, it is possible to make the power amplifier memory circuit 64 smaller and cheaper. While described as normalizing the signal from the transceiver circuit 34, the converse is also possible. The APD circuit 52 could bring the response of the power amplifier circuit 86 to one of a predetermined set of possible responses, allowing the DPD circuit to need fewer coefficients.

The above discussion focuses on the concept of allowing the transceiver circuit (also referred to as a BBP) and the power amplifier circuit (also referred to as a front-end module (FEM)) to split predistortion responsibilities. The split may be based on the type of distortion (AM-AM, AM-PM, memory, memoryless), type of signal, or the like. As noted, the BBP may provide distortion directly within the BBP or may control knobs in the FEM. Likewise, the FEM may control knobs within the FEM. The knobs may include bias signals to power amplifier stages, load line modulation, modulating inter-stage matching circuits or filters, or the like depending on design criteria and the sort of change that may be needed. While this discussion has primarily contemplated that the information used to make the changes comes from the BBP to the FEM, the present disclosure is not so limited. In exemplary aspects, the FEM may provide information back to the BBP to assist the BBP in making predistortion decisions. As alluded to above, one such bit of information is a temperature reading that indicates the temperature of the power amplifier circuit. As the power amplifier amplifies signals, power is dissipated and heat is generated. While there are typically mechanisms to disperse the heat before damaging levels occur, the transient heat surges do change the operation of the circuitry and may contribute to nonlinearities. Accordingly, knowing the temperature fluctuations may allow the BBP or the FEM to apply predistortion so as to counteract heat-induced distortion.

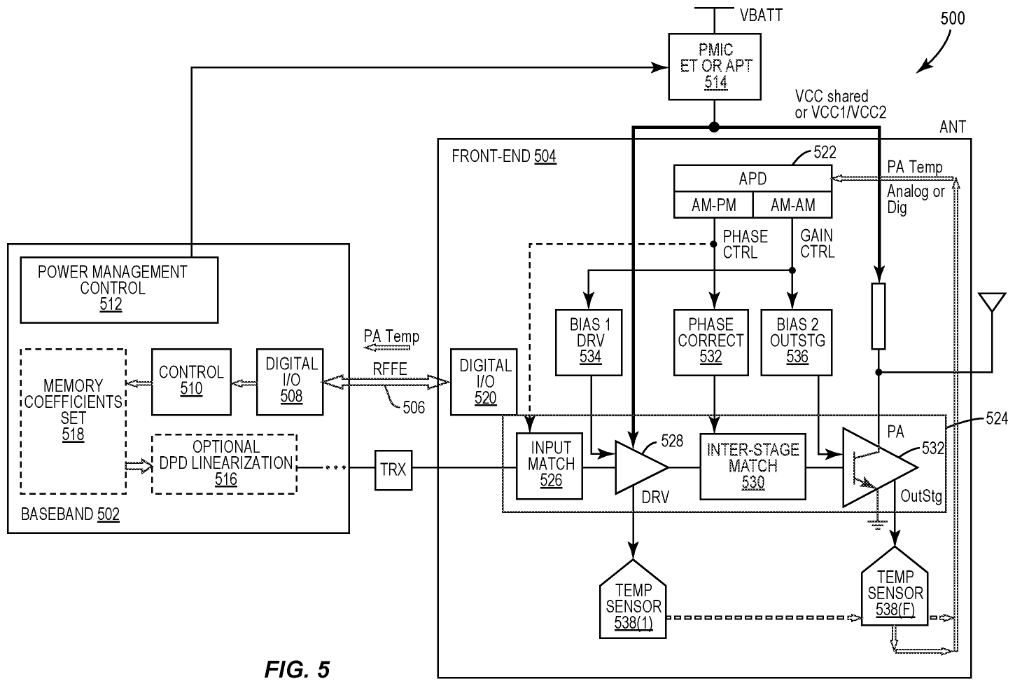

In this regard, FIG. 5 illustrates a transceiver 500 having a BBP 502 and a FEM 504 coupled by a communication bus 506. In an exemplary aspect, the communication bus 506 is a Radio Frequency Front End (RFFE) bus compliant with the RFFE standard published by MIPI. The BBP 502 may include a bus interface 508 that is configured to couple to the communication bus 506 and send information to the FEM 504 as well as receive information form the FEM 504. The BBP 502 may include a control circuit 510 that manages various functions according to exemplary aspects of the present disclosure. The BBP 502 may also include a power management control circuit 512 that includes a bus interface (not shown explicitly) that communicates with a PMIC 514 and may provide information used by the PMIC 514 to perform tracking (e.g., APT or ET). The BBP 502 may further include a DPD circuit 516, which includes, for example, memory coefficient sets in a LUT 518.

The FEM 504 may include a bus interface 520 configured to be coupled to the communication bus 506. Further, the FEM 504 may include an APD circuit 522. Information from the BBP 502 may be used by the APD circuit 522 to adjust knobs in the FEM 504 to assist in linearizing operation of a power amplifier chain 524. The power amplifier chain 524 may include an input matching circuit 526, a driver stage 528, an inter-stage matching circuit 530, and an output stage 532. As described above, the APD circuit 522 may include an AM-AM distortion correction block and an AM-PM distortion correction block and may adjust knobs such as bias circuits 534, 536, the input matching circuit 526, the inter-stage matching circuit 530, a load line (not shown), a phase correction circuit 537, and the like. Still further, the FEM 504 may include one or more temperature sensors 538(1)-538(F) which measure local temperatures and provide a signal to the APD circuit 522. The APD circuit 522 may use this information to adjust the knobs and/or pass this information to the BBP 502. In exemplary aspects, the temperature sensors 538(1)-538(F) may be positioned in the driver stage 528 and/or the output stage 532. The temperature sensors 538(1)-538(F) may be embedded in the circuitry of the respective elements and do not generally measure ambient temperature, but rather measure relatively fast transient temperature changes that occur during normal operation.

The BBP 502 may use the information from the temperature sensors 538(1)-538(F) to adjust the DPD applied by the DPD circuit 516 and/or adjust signals provided to the PMIC 514. To be clear, the changes to the PMIC 514 are optional. Thus, it may be possible to effectuate changes in just the FEM 504, just the BBP 502, both the FEM 504 and BBP 502, just the PMIC 514, both the BBP 502 and the PMIC 514, both the FEM 504 and the PMIC 514, or all three without departing from the present disclosure.

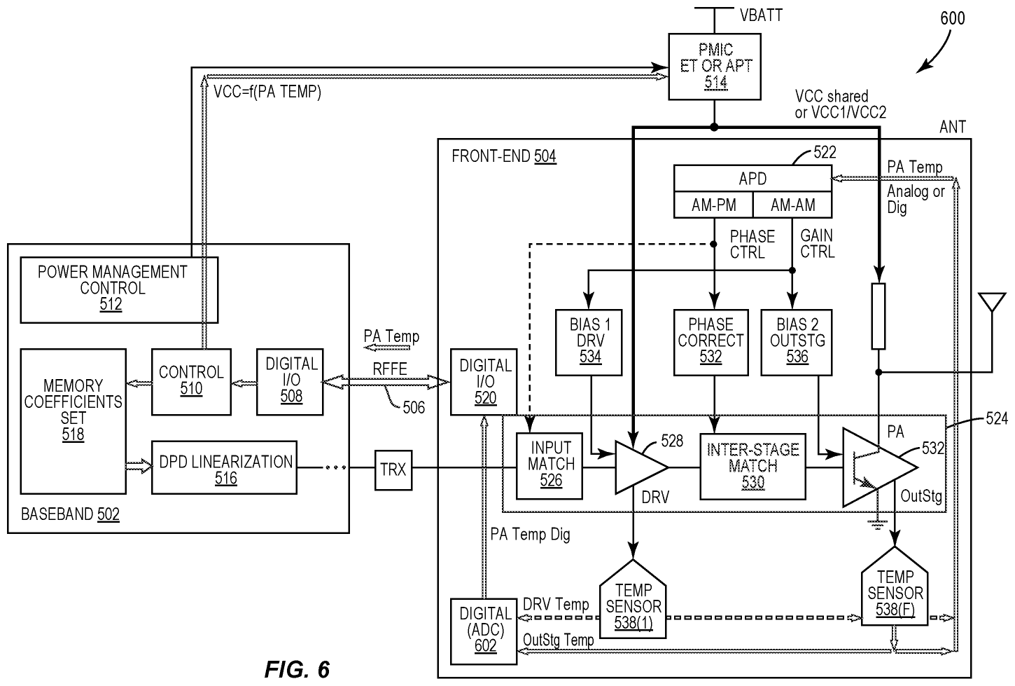

FIG. 6 provides an alternate transceiver 600 that, instead of routing temperature information through the APD circuit 522, may provide the temperature information through an analog-to-digital converter (ADC) 602 and then through the bus interface 520 to the BBP 502. In other regards, the transceiver 600 is substantially similar to the transceiver 500 and duplicated elements are not discussed again.

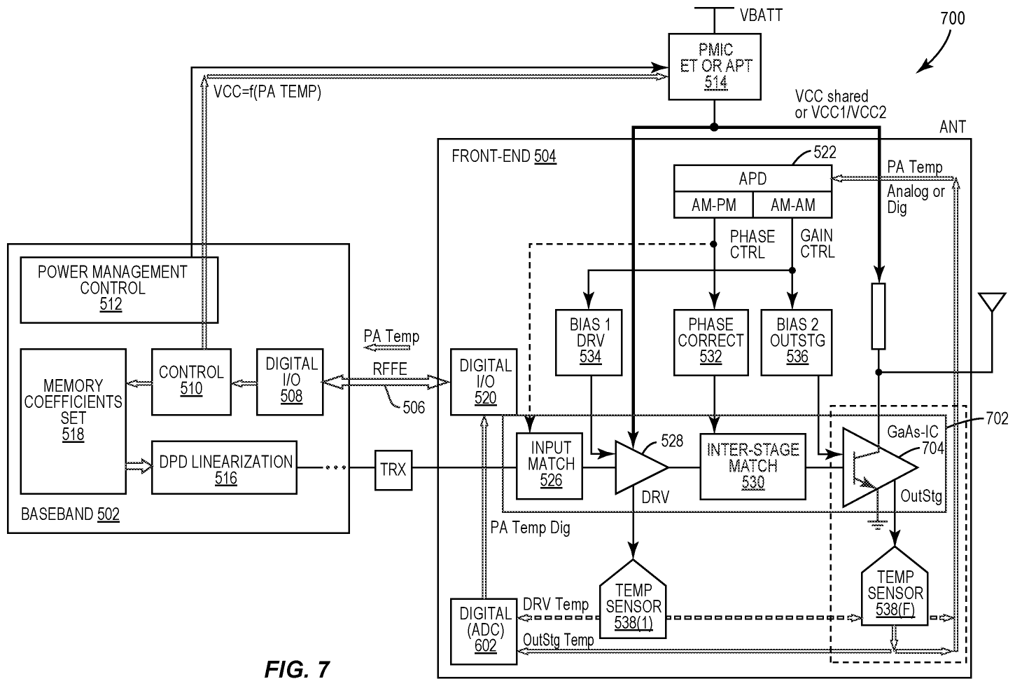

FIG. 7 provides an illustration of a transceiver 700 which includes a mixed technology amplifier chain 702. Specifically, the output stage 704 may be a FET-based technology such as gallium arsenide (GaAs) while other portions are implemented in BJTs. This allows the temperature sensor 538(F) to be a digital sensor if desired. In all other senses, the variations of the transceiver 700 remain the same as those discussed above.

It should be appreciated that the temperature sensors 538(1)-538(F) may do double duty and may be allowed to provide information to an over-temperature protection circuit loop. Specifically, an over temperature protection circuit may be provided which adjusts bias, load line modulation, matching circuits or the like as needed or desired. This sort of throttling may also be done in the BBP 502. Where there are different technologies as with transceiver 700, it may be possible to implement distinct over temperature protection loops on both dies (i.e., both the BJT and the FET dies). For more information about such over temperature protection loops, the interested reader is directed to U.S. patent application Ser. No. 17/488,823, filed Sep. 29, 2021 and U.S. patent application Ser. No. 17/488,877, filed Sep. 29, 2021, both of which are incorporated by reference in their entireties.

Those skilled in the art will recognize improvements and modifications to the preferred aspects of the present disclosure. All such improvements and modifications are considered within the scope of the concepts disclosed herein and the claims that follow.

1. A wireless transmission circuit comprising:
a transceiver circuit comprising:
a digital signal processing circuit configured to generate a digital signal;
a digital predistortion (DPD) circuit configured to perform at least one selected form of DPD on the digital signal; and
a signal conversion circuit configured to convert the predistorted digital signal into a radio frequency (RF) signal; and
a power amplifier circuit comprising an analog predistortion (APD) circuit configured to perform at least one selected form of APD on the RF signal, wherein the APD circuit is further configured to adapt the at least one selected form of APD based on one or more sensor signals.

2. The wireless transmission circuit of claim 1, wherein the DPD circuit and the APD circuit are further configured to perform the at least one selected form of DPD and the at least one selected form of APD concurrently.

3. The wireless transmission circuit of claim 1, wherein:
the APD circuit is further configured to perform the at least one selected form of APD to correct a memoryless distortion in the RF signal; and
the DPD circuit is further configured to perform the at least one selected form of DPD to correct a memory distortion in the RF signal.

4. The wireless transmission circuit of claim 3, wherein the DPD circuit is further configured to perform the at least one selected form of DPD to correct a residual memoryless distortion in the RF signal.

5. The wireless transmission circuit of claim 1, wherein:
the APD circuit is further configured to perform the at least one selected form of APD to correct an amplitude-amplitude (AM-AM) distortion in the RF signal; and
the DPD circuit is further configured to perform the at least one selected form of DPD to correct an amplitude-phase (AM-PM) distortion in the RF signal.

6. The wireless transmission circuit of claim 5, wherein the DPD circuit is further configured to perform the at least one selected form of DPD to correct a residual AM-AM distortion in the RF signal.

7. The wireless transmission circuit of claim 1, wherein:
the APD circuit is further configured to perform the at least one selected form of APD to correct an amplitude-phase (AM-PM) distortion in the RF signal; and
the DPD circuit is further configured to perform the at least one selected form of DPD to correct an amplitude-amplitude (AM-AM) distortion in the RF signal.

8. The wireless transmission circuit of claim 7, wherein the DPD circuit is further configured to perform the at least one selected form of DPD to correct a residual AM-PM distortion in the RF signal.

9. The wireless transmission circuit of claim 1, wherein:
the APD circuit is further configured to perform the at least one selected form of APD to correct an amplitude-amplitude (AM-AM) distortion and an amplitude-phase (AM-PM) distortion in the RF signal; and
the DPD circuit is further configured to perform the at least one selected form of DPD to correct a residual AM-AM distortion and a residual AM-PM distortion in the RF signal.

10. (canceled)

11. The wireless transmission circuit of claim 1, wherein the APD circuit is further configured to adapt the at least one selected form of APD based on information received from the transceiver circuit.

12. The wireless transmission circuit of claim 1, wherein:
the power amplifier circuit further comprises:
a plurality of stage amplifiers configured to amplify the RF signal; and
a plurality of match circuits each coupled to a respective one or two of the plurality of stage amplifiers; and
the transceiver circuit is further configured to selectively control at least one of the plurality of match circuits to thereby change a frequency response of the RF signal.

13. The wireless transmission circuit of claim 1, further comprising a temperature sensor in the power amplifier circuit adapted to generate at least one of the one or more sensor signals.

14. The wireless transmission circuit of claim 13, wherein the temperature sensor is configured to provide temperature information to the APD circuit.

15. The wireless transmission circuit of claim 13, wherein the temperature sensor is configured to provide temperature information to the transceiver circuit.

16. The wireless transmission circuit of claim 15, wherein the transceiver circuit modifies operation of a power management circuit responsive to the temperature information.
